(19) United States
(12) Patent Application Publication
(10) Pub. No.: US 2006/0160266 A1
(43) Pub. Date: Jul. 20, 2006

(54) Organic electronic component and method for producing organic electronic devices

(76) Inventors: Adolf Bernds, Baiersdorf (DE); Alexander Friedrich, Erlangen (DE); Alessandro Manuelli, Spinetta M Go (A1) (IT)

Correspondence Address: CARELLA, BYRNE, BAIN, GILFILLAN, CECCHI,;STEWART & OLSTEIN, 5 BECKER FARM ROAD, ROSELAND, NJ, 07068, US

(21) Appl. No.: 10/542,678

(22) PCT Filed: Jan. 14, 2004
(86) PCT No.: PCT/EP04/00216

§ 371 Date: Dec. 27, 2005

(30) Foreign Application Priority Data
Jan. 21, 2003 (DE) 103 02 146.9

(51) Int. Cl. H01L 51/40

(52) U.S. Cl. 438/99

(57) ABSTRACT

The invention relates to an organic electronic component and a process for low-cost and large-scale production of organic electronics, wherein roll-to-roll compatible coating techniques are used in conjunction with printing processes.

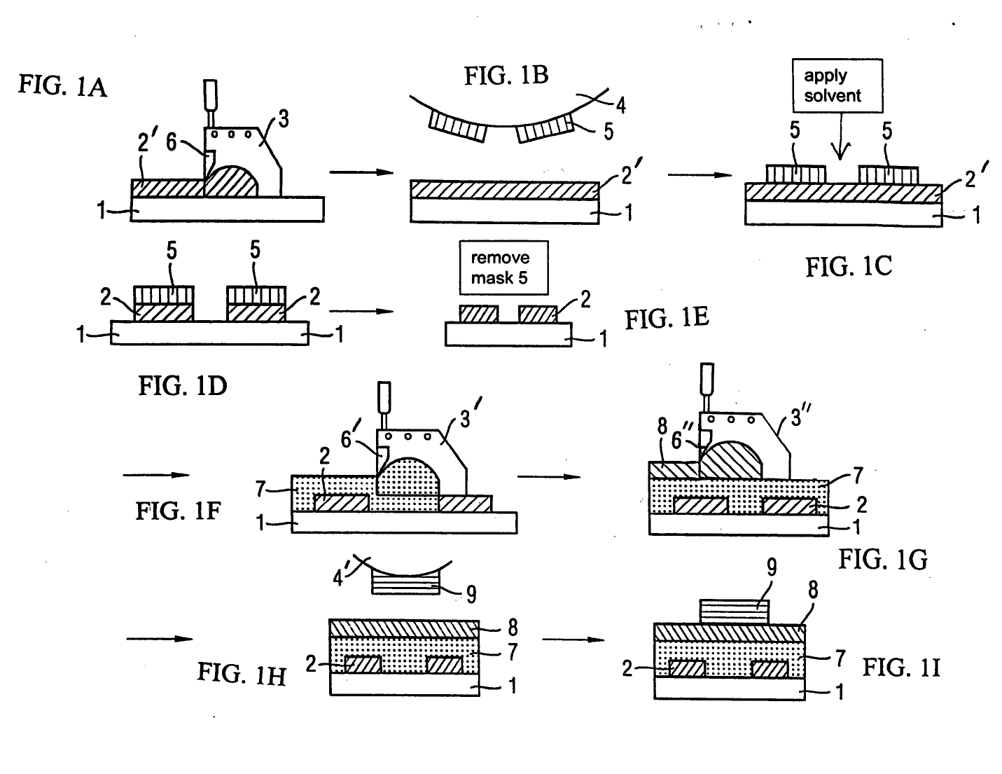

The invention relates to an organic electronic component and to a process for the manufacture of organic electronics that is both cost-effective and suitable for mass production.

The production of organic components through a combination of continuous and non-continuous processes is already known. Thus, for example, coatings devoid of pattern are created using non-continuous (batch) coating processes such as spin coating (with individual wafers being coated one at a time) and coatings in patterned form are obtained by printing or by some other similar roll-to-roll procedure (Eg DE 10033112.2)

Hitherto, the likelihood has been very small that an organic electronic component could have been produced in a single continuous process, because current coating technology, especially spin coating, is not roll-to-roll compatible.

It is an object of the present invention to provide a process that will make it possible to construct an organic electronic component in a roll-to-roll process. Another object of the present invention is to provide an organic electronic component that can be mass-produced in one continuous operation.

Thus, the invention relates to the production of an organic electronic component by a continuous or virtually continuous process. In particular, the invention relates to a process for the production of an organic electronic component using a wholly roll-to-roll procedure. The invention further relates to an organic electronic component that can be manufactured in one continuous, or at least virtually continuous, mass-production process.

In particular, the invention relates to a process for the production of an organic component by a continuous, or at least virtually continuous, procedure comprising the following production steps:
applying a functional (conducting, semi-conducting, or insulating) organic material to a substrate formed by a continuous web or a series of successive sheets,
printing this functional layer with a varnish in patterned form,
providing the functional layer with a pattern by means of said varnish, optionally in further production steps.

Embodiments of the invention will become apparent from the claims, the figures, and the description.

The term organic electronic component refers to an organic field-effect transistor (OFET), an organic photo-voltaic element, an organic diode (in particular, an organic light-emitting diode [OLED]), or some other type of electronic component which comprises at least one conducting or semi-conducting organic functional layer.

One embodiment of the process for continuous production of organic components comprises the following production steps:
applying a functional (conducting) organic material to a substrate formed, for example, by a continuous web or a series of successive sheets, using a continuous coating process,
printing this functional layer with a varnish in patterned form,
providing the conducting layer with a pattern by means of this varnish,
applying a semi-conducting layer over the conducting paths or electrodes thus formed, by a continuous coating process,
applying an insulating coating over the semi-conducting layer likewise by a continuous coating process, and
printing an upper electrode on the insulating layer.

The continuous coating techniques proposed are those which are described in “Coatings Technology Handbook” (2nd edition) Editors: D. Satas and Arthur A. Tracton (Marcel Dekker, N.Y., Basel), Chapter 18 (“Porous Roll Coater”), pp. 165-178; and “Modern Coating and Drying Technology” by Edward D. Cohen and Edgar B. Gutoff (Wiley, Weinheim), pp. 1-10. It is surprising that the processes specified therein are roll-to-roll compatible and may be used for the construction of organic electronics, resulting in homogeneous polymer layers for the construction of organic electronics.

All of these coating techniques are roll-to-roll compatible. The following examples will summarize briefly which techniques are particularly advantageous in the present context:

Porous roll coating has a counterpart in screen printing, except that a porous cylinder takes the place of the screen roller. The coating liquid pushes outwardly from within the cylinder through the pores, either onto another roller and thence onto the web to be coated or else directly onto the web. Its advantage over screen printing resides in the fact that the pores can be made considerably finer than screen openings, and thus much less viscous (thinner) liquids can be used. Porous roll coating is one of the few processes (the only other being gravure coating) which allow for application in patterned form (direct patterning) by masking pores locally, ie it is suitable for coating as well as for printing.

Other processes include:

Dip coating, in which a continuous web is drawn though at least one liquid; rod coating, in which the web is drawn tangentially over a roller or drum that has already been wetted with the liquid; blade coating, in which a web bears against a drum that passes a container filled with the liquid, the container being closed on two sides, de-limited on the third side by the drum and on the fourth side by a doctor blade located at a distance above the web such that the liquid at the level of the doctor blade above the web is held back in the container and does not adhere to the web.

An additional roll-to-roll compatible coating technique is air knife coating, which is similar to dip coating except for the presence of a fan, by means of which the liquid on the web that has been drawn through the liquid, is dried and/or blown off at a certain point.

These four coating processes are already known for use in the manufacture of other polymer coatings, and they are described and illustrated by drawings in the texts cited above. Further roll-to-roll compatible coating processes include gravure coating, in which two drums of unequal size are rotated in the same direction in contact with each other, the larger drum having been immersed in the liquid, whilst the web bears against the smaller drum, the thickness of the wet layer transferred by the larger drum to the smaller drum being controlled by a doctor knife mounted on the larger drum. Another process is reverse roll coating, in which two drums rotating in opposite directions are pressed against one another, with one drum being wetted by the liquid while the continuous web is drawn past the other drum.

Finally, the techniques described in said reference—forward roll coating, slot and extrusion coating, slide coating, and curtain coating—are particularly advantageous, though no special significance should be inferred from the order in which they are described and/or named therein. Finally, there is also spray coating, which is self-explanatory.

The advantage of coating techniques in general for organic electronics resides in the fact that they can be used to produce thin homogeneous coatings (thickness about 0.02 to 2.0 μm) in one continuous operation. Since the said coating techniques do not themselves confer any pattern, they can only be used in conjunction with pattern-conferring processes such as the printing techniques. By combining roll-to-roll compatible coating techniques with roll-to-roll printing processes, it is possible to make all the steps required for producing an organic electronic component roll-to-roll compatible.

A “roll-to-roll process” refers to a process that is continuous and involves web-like materials in the sense mentioned above, ie webs or a series of sheets, and in which substantially rollers or drums are used for coating, for printing, and/or for other processing steps.

The phrase “construction of an organic electronic component” refers to the basic elements of an organic electronic component. “Substrate” refers to a web-like material in the above-mentioned sense, ie a material suitable for web feeding and sheet feeding, and forming the carrier on which there are disposed a lower electrode, a semi-conducting photo-voltaic active and/or emitting layer, one or more insulating layers, and an upper electrode.

By “mass production” is meant a production method that allows for and/or makes possible the manufacture of low-cost products such as disposable chips by way of simple production steps at a high throughput rate, ie with the production of a large number of pieces per unit of time and optimal utilization of machines, and with the avoidance of dwell times in machines, etc.

A “continuous process” refers to production that is not executed batchwise but steadily, such as production on a continuous band. In non-continuous processes, ie batch production processes, insertion of the materials into the machine and subsequent unloading of the newly produced article from the machine occupies too much time to make low-cost production possible. The significance of the term “continuous production” here is the implication of the advantages gained by an assembly line. A virtually continuous process may include short pauses in the manufacturing chain, but it will entail two or more continuously-running, linked production steps.

According to one embodiment, the organic electronic component is a field-effect transistor comprising at least a substrate, a lower source/drain electrode, a semi-conducting layer, an insulating layer, and an upper electrode.

“Indirect patterning” refers to a method of producing a pattern in which a layer (of varnish, etc.) that has been applied to a previously applied layer for the sole purpose of imparting pattern thereto, is itself provided with a pattern. “Direct patterning” means, accordingly, imparting pattern to a layer by direct means.

According to one embodiment of the process, the respective coating and printing processes are preceded by conditioning processes for, say, cleaning and/or pretreating the surface, using, for example, corona, flame, ultraviolet, or plasma treatment, and/or some other process.

According to another embodiment of the process, the respective coating and printing processes are followed by at least one drying or curing process by applying, say, heat, ultraviolet light, or infrared light, or by some other process.

The invention is explained below in more detail with reference to the manufacture of an organic field-effect transistor by way of example.

The FIGURE shows the steps in the process of making lower electrode(s) 2, a semi-conducting layer 7, an insulating layer 8, and an upper electrode 9 on a substrate consisting of a web 1, to which a functional organic material, in particular a conducting polymer 2, is applied by a continuous coating technique. The organic functional material may be dissolved or dispersed in one or more organic or inorganic solvents, or it may be in the form of a pure material, a mixture of materials, and/or a material provided with additives.

The continuous coating method involves the use of a doctor knife 6, which forms an integral part of a machine 3. To coating 2 there is applied a varnish 5 in patterned form with the aid of a roller 4, by means of which varnish a pattern is imparted to the lower electrode(s). To the patterned lower electrode(s) there is applied a semi-conducting layer 7 again by means of a machine 3 provided with a doctor knife 6. Over this layer there is placed an insulating layer 8, again by means of a coating technique, and, finally, an upper electrode 9 is applied in patterned form to said layer 8 (direct patterning). Machine 3 is preferably combined with a roller for dip coating, rod coating, knife coating, blade coating, air knife coating, gravure coating, forward and reverse roll coating, slot and extrusion coating, slide coating, curtain coating, and/or spray coating, as mentioned above in the cited literature and in the above description. The process proposed herein provides, for the first time, the possibility of a continuous roll-to-roll coating process for cost-efficient mass production of organic electronic components. Hitherto, the only continuous processes known were those involving printing technology, and the problem with them was that none of the printing techniques could create thin layers having sufficient homogeneity for organic electronics.

With the help of the invention, all kinds of organic electronic components may be manufactured in a continuous mass-production process. These include, inter alia, organic transistors and their circuits, organic diodes, organic-based capacitors, organic photo-voltaic cells, organic sensors and actuators, and combinations thereof.

1. A process for the production of an organic electronic component comprising a plurality of organic based functional layers, wherein at least one of the functional organic based layers is applied in a continuous process step in the form of a homogenous, unpatterned coating obtained by a roll-to-roll compatible process selected from the group consisting of one of porous roll coating, dip coating, rod coating, knife coating, blade coating, air knife coating, gravure coating, forward and reverse coating, slot and extrusion coating, slide coating, curtain coating, and spray coating

2. A process for applying a homogenous and unpatterned coating of an organic electronic component, which is carried out in a wholly roll-to-roll process on a web or individual sheets.

3. (canceled)

4. A process as defined in any one of the previous claims, wherein said layers are directly or indirectly patterned in a subsequent process step.

5. A process for the continuous production of an organic component, comprising the following production steps:
applying to a substrate which is a continuous, coherent web or sheet feed comprising a succession of individual sheets, by a continuous coating method, a functional organic material layer, which is one of conducting, semiconducting or insulating material, as a homogenous, unpatterned coating;
printing a varnish in patterned form over the functional layer; and
patterning the functional layer by means of the varnish directly or via further process steps.

6. A process as defined in claim 5 wherein at least one pretreatment step is carried out prior to the coating or printing process.

7. A process as defined in any one of claims 5 or 6 wherein the respective coating and/or patterning step is followed by after treatment of the layer.

8. A process as defined in any one of claims 5 or 6 wherein patterning of the layers is carried out in a roll-to-roll compatible process and including any one selected from the group consisting of gravure printing, planographic printing (offset), letterpress printing (flexographic printing), ink jet printing, laser printing, or by combinations thereof and related processes.

9. An electronic component, constructed by one or more of the processes as defined in any one of claims 1-2 and 5-6.
